(19) United States
(12) Patent Application Publication
(10) Pub. No.: US 2012/0007169 A1
(43) Pub. Date: Jan. 12, 2012

(54) SEMICONDUCTOR DEVICE AND ITS PRODUCTION METHOD

(75) Inventors: Satoshi HIKIDA, Osaka (JP); Takayoshi HASHIMOTO, Osaka (JP)

(73) Assignee: SHARP KABUSHIKI KAISHA, Osaka (JP)

(21) Appl. No.: 13/177,977

(22) Filed: Jul. 7, 2011

(30) Foreign Application Priority Data
Jul. 8, 2010 (JP) 2010-155928

(51) Int. Cl. H01L 29/78; H01L 21/336

(52) U.S. Cl. 257/328; 438/268; 257/E29.262; 257/E21.41

(57) ABSTRACT

The present invention provides a semiconductor device including:a semiconductor substrate of a first conductive type; a first well region of the first conductive type formed in the semiconductor substrate; an epitaxial region of a second conductive type formed in the semiconductor substrate and arranged in a region adjacent to the first well region; a buried region of the second conductive type that is formed in a region at a lower part of the epitaxial region and that has an impurity concentration higher than that of the epitaxial region; a trench formed at boundaries between the first well region and the epitaxial region, and between the first well region and the buried region; a first semiconductor element that is formed on the first well; and a second semiconductor element that is formed on the epitaxial region.

### CROSS-REFERENCE TO RELATED APPLICATION

This application is related to Japanese Patent Application No. 2010-155928 filed on Jul. 8, 2010, whose priority is claimed and the disclosure of which is incorporated by reference in its entirety.

### BACKGROUND OF THE INVENTION

1. Field of the Invention

The present invention relates to a semiconductor device, and its production method, and more particularly to a CMOS transistor and its production method.

2. Description of the Background Art

A CMOS (complementary MOS) structure is a structure in which an N-channel MOS transistor and a P-channel MOS transistor are simultaneously integrated. This structure has widely been used in many semiconductor device circuits. For example, this structure is applied even to a circuit that requires a high breakdown voltage such as a liquid crystal driver.

However, it has been known that, in the COMS structure, a parasitic bipolar transistor is formed between adjacent regions, and by virtue of the action of this transistor, a latch up is caused. Therefore, a semiconductor device circuit having the CMOS structure employs a layout structure for preventing the latch up in the CMOS structure.

For example, a semiconductor device has been known, the device having a well guard ring provided at a boundary between a well region of an N-channel MOS transistor and a well region of a P-channel MOS transistor. A semiconductor device having a deep trench formed at the boundary has also been known (e.g., see Japanese Unexamined Patent Publication No. 2007-227920).

A conventional semiconductor device will be described below with reference to FIGS. 13 and 14. FIG. 13 is a sectional view for describing a semiconductor device formed with a well guard ring. FIG. 14 is a sectional view for describing a semiconductor device formed with a deep trench.

As shown in FIG. 13, the semiconductor device having the well guard ring includes an N-type well region 103, which is formed on a P-type semiconductor substrate 101, and which has a PMOS transistor 150 (hereinafter also referred to as a P-channel type MOS transistor. The same shall apply hereinafter) arranged thereon, and a P-type well region 104, which is formed on the substrate 101, and which has an NMOS transistor 151 (hereinafter also referred to as an N-channel type MOS transistor. The same shall apply hereinafter) arranged thereon. Well guard rings 120 and 121 are formed in the vicinity of a boundary between the N-type well region 103 and the P-type well region 104. The well guard rings 120 and 121 are connected to a power supply line, wherein a VDD potential is applied to the well guard ring 120. A GND potential (or VSS potential) is applied to the well guard ring 121. In the semiconductor device having the well guard rings, the well guard rings 120 and 121 are set to have the above-mentioned potential, in order to prevent the occurrence of the latch up.

As shown in FIG. 14, the semiconductor device having the deep trench formed thereon includes an N-type well region 103, which is formed on a P-type semiconductor substrate 101, and which has a PMOS transistor 150 arranged thereon, and a P-type well region 104, which is formed on the substrate 101, and which has an NMOS transistor 151 arranged thereon. A deep trench 130 that is deeper than these well regions is formed at the boundary between the N-type well region 103 and the P-type well region 104. In the semiconductor device having the deep trench formed thereon, a current amplification factor h_{FE} of a transverse NPN bipolar transistor 200 formed from the N-type well region 103, the P-type semiconductor substrate 101, and an NMOS source/drain region 113 is reduced so as to prevent the occurrence of the latch-up.

However, the above-mentioned semiconductor device having the well guard rings needs a region where the well guard rings are to be arranged. The region other than the region where the transistor is to be formed has to be newly formed, so that the size of the semiconductor device is liable to increase. Therefore, a semiconductor device that can prevent the occurrence of the latch up with a more compact size has been desired.

For example, in a circuit requiring a high breakdown voltage (e.g., liquid crystal driver), the number of the semiconductor devices integrated thereon is dramatically increased with the increased performance and the increased function, like the semiconductor device circuit, which entails an increase in size of the semiconductor device. Due to the application of an electrostatic discharge protection device in addition to the layout for preventing the latch up, the size of the semiconductor device is liable to increase. Therefore, even in the circuit requiring the high breakdown voltage, it has been desired that the occurrence of the latch up is prevented as well as the size of the semiconductor device is decreased.

The semiconductor device having the deep trench formed thereon as described above does not need to have a region other than the region where the transistor is to be formed, but has to need to increase the region where the deep trench is to be formed. In case where it is used for the circuit requiring the high breakdown voltage, the size of the semiconductor device is not so decreased. Specifically, an impurity concentration of a base region of the transverse NPN bipolar transistor 200 is determined by the P-type semiconductor substrate 101 and the P-type well region 104. Therefore, when it is used for a transistor having a high breakdown voltage, the concentrations of the impurities cannot be increased. Accordingly, the region where the deep trench is to be formed is increased, and further, the width of the base region has to be increased. Consequently, the size of the semiconductor device is not so decreased.

In the semiconductor device having the deep trench formed thereon, the deep trench 130 does not affect the current amplification factor h_{FE} of a vertical PNP bipolar transistor 300 composed of the P-type well region 104, the N-type well region 103, and a PMOS source/drain region 112. Therefore, a countermeasure such as the formation of the well guard ring is required. Accordingly, the size of the semiconductor device is liable to increase.

As described above, a semiconductor device has been desired, which can prevent the occurrence of the latch up with a more reduced size even in case where the circuit requiring the high breakdown voltage is formed.

### SUMMARY OF THE INVENTION

The present invention has been made in consideration of the problem described in the foregoing, and an object thereof is to provide a semiconductor device that can prevent the occurrence of the latch up with a more reduced size. The present invention also provides a semiconductor device that can maintain a high breakdown voltage.

In order to achieve the above object, the present invention provides a semiconductor device including: a semiconductor substrate of a first conductive type; a first well region of the first conductive type formed in the semiconductor substrate; an epitaxial region of a second conductive type formed in the semiconductor substrate and arranged in a region adjacent to the first well region; a buried region of the second conductive type that is formed in a region at a lower part of the epitaxial region and that has an impurity concentration higher than that of the epitaxial region; a trench formed at boundaries between the first well region and the epitaxial region, and between the first well region and the buried region; a first semiconductor element that is formed on the first well region and that has source and drain regions of the second conductive type; and a second semiconductor element that is formed on the epitaxial region and has source and drain regions of the first conductive type, wherein the semiconductor substrate has an impurity concentration higher than that of the first well region, and the trench is formed so as to be deeper than the first well region and the buried region.

Since the semiconductor device according to the present invention includes a semiconductor substrate of a first conductive type; a first well region of the first conductive type formed in the semiconductor substrate; an epitaxial region of a second conductive type formed in the semiconductor substrate and arranged in a region adjacent to the first well region; a buried region of the second conductive type that is formed in a region at a lower part of the epitaxial region and that has an impurity concentration higher than that of the epitaxial region; a trench formed at boundaries between the first well region and the epitaxial region, and between the first well region and the buried region; a first semiconductor element that is formed on the first well region and that has source and drain regions of the second conductive type; and a second semiconductor element that is formed on the epitaxial region and has source and drain regions of the first conductive type, wherein the semiconductor substrate has an impurity concentration higher than that of the first well region, and the trench is formed so as to be deeper than the first well region and the buried region.

Therefore, this structure can increase the impurity concentration of a base region of a transverse bipolar transistor composed of the source and drain regions of the second conductive type formed on the first well region, the first well region and the semiconductor substrate, and the epitaxial region and the buried region.

Consequently, a current amplification factor h_{FE} of the transverse bipolar transistor can be reduced.

This structure can also increase an impurity concentration of a base region of a vertical bipolar transistor composed of the source and drain regions of the first conductive type formed on the epitaxial region, the epitaxial region and the buried region, and the semiconductor substrate and the first well region. Consequently, a current amplification factor h_{FE} of the vertical bipolar transistor can be reduced.

Accordingly, the semiconductor device according to the present invention can reduce the current amplification factor h_{FE} of the transverse and vertical bipolar transistors, which are parasitic transistors, so as to prevent the occurrence of the latch up in the semiconductor device having the source and drain regions of the second conductive type formed on the first well region, and having the source and drain regions of the first conductive type formed on the epitaxial region.

The semiconductor device according to the present invention does not need to have a new region other than a region where the transistor is to be formed. Further, the semiconductor device according to the present invention can reduce the current amplification factor h_{FE} of not only the transverse bipolar transistor but also the vertical bipolar transistor. Consequently, the semiconductor device according to the present invention can prevent the occurrence of the latch up with the more reduced size.

### BRIEF DESCRIPTION OF THE DRAWINGS

FIG. 1 is a conceptual sectional view of a semiconductor device according to a first embodiment of the present invention;

FIG. 2 is a circuit diagram for describing a diode of the semiconductor device according to the first embodiment of the present invention;

FIG. 3 is a view illustrating a production process of the semiconductor device according to the first embodiment of the present invention;

FIG. 4 is a view illustrating the production process of the semiconductor device according to the first embodiment of the present invention;

FIG. 5 is a view illustrating the production process of the semiconductor device according to the first embodiment of the present invention;

FIG. 6 is a conceptual sectional view of a semiconductor device according to a second embodiment of the present invention;

FIG. 7 is a view illustrating a production process of the semiconductor device according to the second embodiment of the present invention;

FIG. 8 is a view illustrating the production process of the semiconductor device according to the second embodiment of the present invention;

FIG. 9 is a view illustrating the production process of the semiconductor device according to the second embodiment of the present invention;

FIG. 10 is a view illustrating the production process of the semiconductor device according to the second embodiment of the present invention;

FIG. 11 is a view illustrating the production process of the semiconductor device according to the second embodiment of the present invention;

FIG. 12 is a view illustrating the production process of the semiconductor device according to the second embodiment of the present invention;

FIG. 13 is a sectional view for describing a semiconductor device having a well guard ring according to a background art of the present invention; and

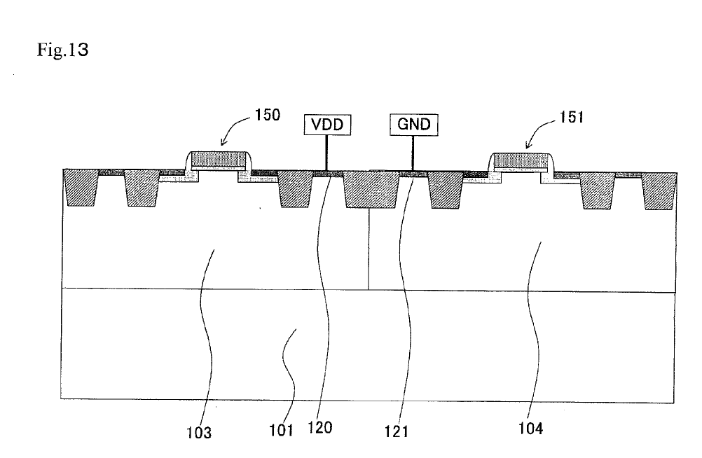

FIG. 14 is a sectional view for describing a semiconductor device having a deep trench formed thereon according to a background art of the present invention.

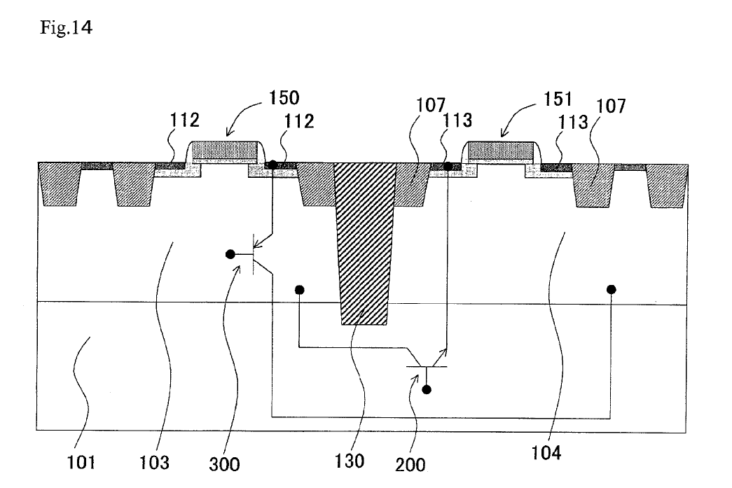

### DESCRIPTION OF THE PREFERRED EMBODIMENTS

A semiconductor device according to the present invention includes a semiconductor substrate of a first conductive type; a first well region of the first conductive type formed in the semiconductor substrate; an epitaxial region of a second conductive type formed in the semiconductor substrate and arranged in a region adjacent to the first well region; a buried region of the second conductive type that is formed in a region at a lower part of the epitaxial region and that has an impurity concentration higher than that of the epitaxial region; a trench formed at boundaries between the first well region and the epitaxial region, and between the first well region and the buried region; a first semiconductor element that is formed on the first well region and that has source and drain regions of the second conductive type; and a second semiconductor element that is formed on the epitaxial region and has source and drain regions of the first conductive type, wherein the semiconductor substrate has an impurity concentration higher than that of the first well region, and the trench is formed so as to be deeper than the first well region and the buried region.

Here, the first conductive type means an N-type or a P-type conductive type, while the second conductive type means a conductive type different from the first conductive type. For example, when the first conductive type is an N-type, the second conductive type is a P-type. When the first conductive type is a P-type, the second conductive type is an N-type.

For example, the semiconductor substrate may be an N-type semiconductor substrate, or a P-type semiconductor substrate.

The buried region is formed in the region at the lower part of the epitaxial region. However, the buried region may be formed below the epitaxial region in the semiconductor substrate. Specifically, the buried region includes a form in which the buried region is formed at the lower part of the epitaxial region after the epitaxial region is formed in the semiconductor substrate, by which the buried region is formed below the epitaxial region in the semiconductor substrate.

In the embodiment of the present invention, in addition to the structure of the invention described above, the semiconductor substrate preferably has three times to ten times as much impurity concentration as the first well region. The semiconductor substrate more preferably has five times to ten times as much impurity concentration as the first well region.

By virtue of this structure, the impurity concentration of the semiconductor substrate serving as a base region of the transverse bipolar transistor is high, resulting in that the current amplification factor h_{FE} of the transverse bipolar transistor can be reduced.

For example, the impurity concentration of the semiconductor substrate is preferably 5.0×10¹⁶ to 2.0×10¹⁷/cm³, and the impurity concentration of the first well region is preferably 2.0×10¹⁶ to 7.0×10¹⁶/cm³.

In the embodiment of the present invention, in addition to the structure of the invention described above, the buried region preferably has 100 times to 1000 times as much impurity concentration as the epitaxial region. The buried region preferably has 300 times to 600 times as much impurity concentration as the epitaxial region.

By virtue of this structure, the impurity concentration of the semiconductor substrate serving as a base region of the vertical bipolar transistor is high, resulting in that the current amplification factor h_{FE} of the vertical bipolar transistor can be reduced.

For example, the impurity concentration of the buried region is preferably 1.0×10¹⁸ to 1.0×10¹⁹/cm³, and the impurity concentration of the epitaxial region is preferably 1.0×10¹⁶ to 1.0×10¹⁷ /cm³.

In the embodiment of the present invention, the semiconductor substrate and the epitaxial region may form a diode so as to protect the second semiconductor element.

When a serge voltage is applied to either one of the source and the drain regions of the second semiconductor element or a second contact region, this structure can protect the second semiconductor element serving as an internal element. Therefore, an electrostatic discharge protection device does not have to newly be provided, resulting in that a semiconductor device having an electrostatic discharge protection device can be provided with a more reduced size.

Specifically, the semiconductor device having the structure described above functions as an element (electrostatic discharge protection device or ESD device) for protecting a semiconductor element (including a circuit) from overvoltage. The overvoltage here includes an abnormal voltage such as a static electricity or short-circuit voltage.

In the embodiment of the present invention, in addition to the structure of the invention described above, a shallow trench for isolating the first or the second semiconductor element may be formed in the first well region or in the epitaxial region.

By virtue of this structure, the element formed in the first well region or in the epitaxial region can be insulated and isolated, whereby a parasitic bipolar transistor is difficult to be formed at the adjacent region. Therefore, a semiconductor device can be provided in which a latch up is difficult to be caused at a portion other than the transverse and vertical bipolar transistors.

According to another aspect, the present invention provides a production method of a semiconductor device, the method including: a step of forming an epitaxial region of a second conductive type on a semiconductor substrate of a first conductive type; a step of forming a trench in the epitaxial region, the trench being deeper than the epitaxial region; a step of forming a first well region of the first conductive type in a region being in the epitaxial region and being adjacent to the trench,; a step of forming a buried region of the second conductive type in a region that is at a lower part of the epitaxial region, is adjacent to the trench, and sandwiches the trench with the first well region, the buried region having an impurity concentration higher than that of the epitaxial region; a step of forming source and drain regions of the second conductive type on the first well region; and a step of forming source and drain regions of the first conductive type on the epitaxial region, wherein the semiconductor substrate has an impurity concentration higher than that of the first well region formed in the step of forming the first well region.

This invention can provide a production method of a semiconductor device that can reduce the current amplification factor h_{FE} of the transverse and vertical bipolar transistors so as to prevent the occurrence of the latch up. The invention can also provides a production method of a semiconductor device that can prevent the occurrence of the latch up with a more reduced size.

In the embodiment of the production method of the present invention, the semiconductor substrate may have three times to ten times as much impurity concentration as the first well region formed by the step of forming the first well region.

In the embodiment of the production method of the present invention, the buried region formed by the step of forming the buried region may have 100 times to 1000 times as much impurity concentration as the epitaxial region formed by the step of forming the epitaxial region.

In addition to the steps described above, the production method of the present invention may further include a step of forming a shallow trench, which isolates the source and drain regions from the other regions, in the first well region or in the epitaxial region.

The present invention will be described in detail below with reference to the drawings.

### First Embodiment

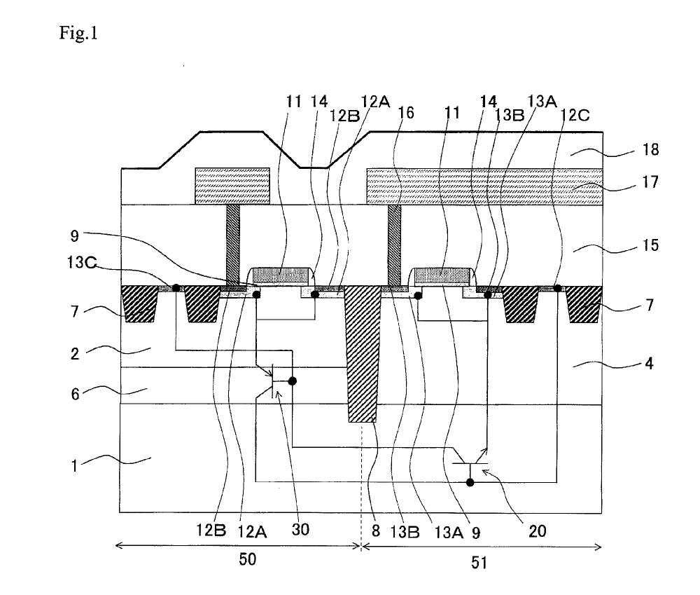

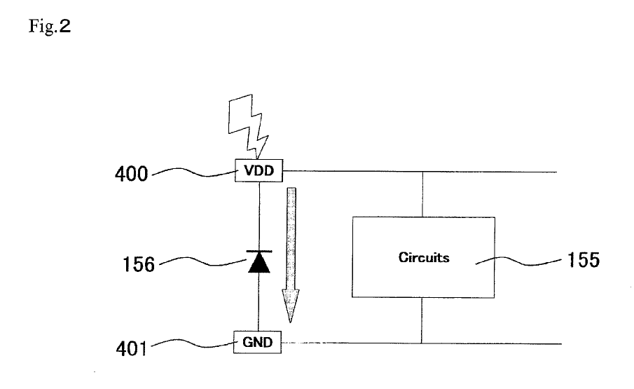

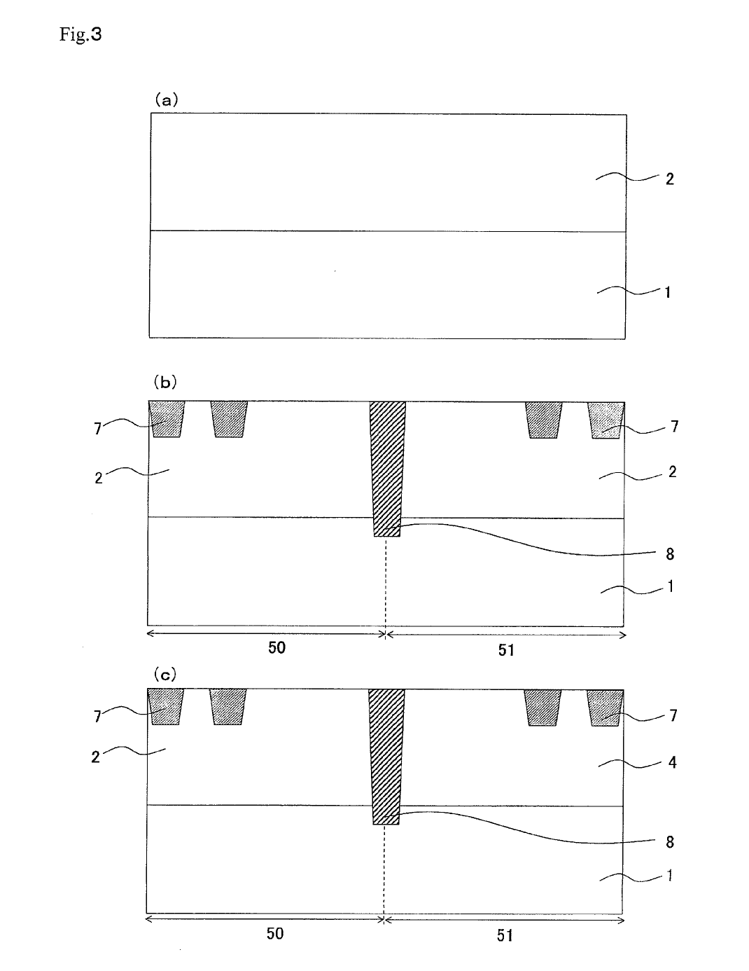

A semiconductor device according to a first embodiment of the present invention will be described with reference to FIGS. 1 to 5. FIG. 1 is a sectional view for describing the semiconductor device according to the present embodiment. FIG. 2 is a circuit diagram for describing a diode of the semiconductor device according to the present embodiment. FIGS. 3 to 5 are views illustrating a production process of the semiconductor device according to the present embodiment.

As illustrated in FIG. 1, the semiconductor device according to the present embodiment includes a P-type semiconductor substrate 1, a P-type well region 4 formed on a partial region of the P-type semiconductor substrate 1, an N-type epitaxial layer 2 formed on another partial region of the P-type semiconductor substrate 1 and arranged adjacent to the P-type well region 4, and an N-type buried layer 6 formed at a lower part of the N-type epitaxial layer 2.

The P-type semiconductor substrate 1 has an impurity concentration of P-type impurities of 1×10¹⁷/cm³, for example. This concentration is selected according to an operation voltage of the semiconductor device. For example, when the semiconductor device needs an absolute maximum rating that is 20 V, the impurity concentration is set to be 1×10¹⁷/cm³. Boron (B) may be used as a P-type impurity, for example.

The P-type well region 4 is formed on a region of the P-type semiconductor substrate 1, and has an impurity concentration of the P-type impurity of 3×10¹⁶/cm³, for example. A transverse bipolar transistor 20 is parasitic in the semiconductor device according to the present embodiment. Considering that a current amplification factor h_{FE} of the transverse bipolar transistor 20 is reduced, it is desirable that a base concentration of the transverse bipolar transistor is increased by using the P-type semiconductor substrate 1 having the high impurity concentration. Therefore, it is preferable that the impurity concentration of the P-type well region 4 and the impurity concentration of the P-type semiconductor substrate 1 differ by a factor of 3 or more.

For example, the impurity concentration of the P-type semiconductor substrate 1 is preferably 6.0×10¹⁶ to 2.0×10¹⁷/cm³, and the impurity concentration of the P-type well region 4 is preferably 2.0×10¹⁶ to 6.0×10¹⁶/cm³.

After the N-type epitaxial layer 2 is formed, the P-type well region 4 is formed by implanting boron into a region of the formed N-type epitaxial layer 2. Therefore, the P-type well region 4 has a thickness (depth of the region) same as the N-epitaxial layer 2 and the N-type buried layer 6 formed in the same manner. The thickness, i.e., the depth of the P-type well region 4 is set to be 3.0 μm.

The N-type epitaxial layer 2 is formed on another partial region of the P-type semiconductor substrate 1 and arranged adjacent to the P-type well region 4 across a deep trench 8. The impurity concentration of an N-type impurity in the N-type epitaxial layer 2 is 1.0×10¹⁶/cm³, for example. The impurity concentration is preferably 5.0×10¹⁵ to 5.0×10¹⁶/cm³.

The thickness of the N-type epitaxial layer 2 is 3.0 μm.

The N-type buried layer 6 is formed below the N-type epitaxial layer 2 in such a manner that the region thereof is in contact with the region of the N-type epitaxial layer 2. The N-type buried layer 6 has an impurity concentration higher than that of the N-type epitaxial layer. For example, the impurity concentration of the N-type impurity is 1.0×10¹⁹/cm³. Preferably, the impurity concentration is 5.0×10¹⁸ to 2.0×10¹⁹/cm³.

In the semiconductor device according to the present embodiment, a vertical bipolar transistor 30 is parasitic in addition to the transverse bipolar transistor 20. Considering that a current amplification factor h_{FE} of the vertical bipolar transistor 30 is reduced, it is preferable that the impurity concentration of the N-type buried layer 6 and the impurity concentration of the N-type epitaxial layer differ by a factor of 100 to 1000, more preferably by a factor of 300 to 600.

After the N-type epitaxial layer is formed on the P-type semiconductor substrate 1, the N-type buried layer 6 is formed by implanting an impurity into the formed N-type epitaxial layer. Therefore, the N-type buried layer 6 has a depth to the lower boundary (lower surface) same as that of the P-type well region 4 (formed also by implanting the impurity into the formed N-type epitaxial layer) formed in the same manner. Specifically, the boundary between the N-type buried layer 6 and the P-type semiconductor substrate 1 is arranged at the same depth of the boundary between the P-type well region 4 and the P-type semiconductor substrate 1. In the present embodiment, the depth of the P-type well region 4 is 3.0 μm, and the thickness of the N-type epitaxial layer 2 after the impurity is implanted is 2.0 μm, so that the thickness of the N-type buried layer 6 is 1.0 μm.

As illustrated in FIG. 1, the deep trench 8 is formed at the boundary between the P-type well region 4, and the N-type epitaxial layer 2 and the N-type buried layer 6 in the semiconductor device according to the present embodiment. A PMOS transistor is formed on the N-type epitaxial layer 2, while an NMOS transistor is formed on the P-type well region 4.

The deep trench 8 has a depth of 3 to 6 μm. As described above, the boundary between the N-type buried layer 6 and the P-type semiconductor substrate 1 is at the same depth of the boundary between the P-type well region 4 and the P-type semiconductor substrate 1. Further, the thickness of the P-type well region 4 and the thicknesses of the N-type epitaxial layer 2 and the N-type buried layer 6 are the same. Therefore, when the depth of the deep trench 8 is larger than the thickness of the P-type well region 4 (or the thicknesses of the N-type epitaxial layer 2 and the N-type buried layer 6), the deep trench 8 is formed to be deeper than the P-type well region 4 and the N-type buried layer 6. Since the depth of the P-type well region 4 is 3.0 μm in the present embodiment as described above, the deep trench 8 is formed to be deeper than the P-type well region 4 and the N-type buried layer 6. Accordingly, in the present embodiment, a PMOS transistor region 50 and an NMOS transistor region 51 are electrically isolated.

The PMOS transistor includes PMOS source/drain electric-field relaxation regions 12A arranged so as to sandwich a channel region of the N-type epitaxial layer 2, and a gate electrode 11 arranged on the channel region via a gate oxide film 9. PMOS high-concentration source/drain regions 12B are formed on the surface of the PMOS source/drain electric-field relaxation regions 12A. The PMOS high-concentration source/drain regions 12B are connected to a metal wiring 17 through a contact hole 16. The PMOS transistor is a high breakdown voltage transistor and formed to receive an input/output signal from the metal wiring 17.

The impurity concentration of the P-type impurity of the PMOS source/drain electric-field relaxation regions 12A is 4.0×10¹⁶ to 8.0×10¹⁶/cm³.

The region where the PMOS transistor is formed is isolated by a shallow trench 7. For example, a contact region 12C that is isolated from the PMOS source/drain electric-field relaxation regions 12A is formed, and the contact region 12C is isolated by the shallow trench 7.

The NMOS transistor has the same structure as the PMOS transistor. It includes NMOS source/drain electric-field relaxation regions 13A arranged so as to sandwich a channel region of the P-type well region 4, and the gate electrode 11 arranged on the channel region via the gate oxide film 9. NMOS high-concentration source/drain regions 13B are formed on the surface of the NMOS source/drain electric-field relaxation regions 13A. The NMOS high-concentration source/drain regions 13B are connected to the metal wiring 17 through the contact hole 16. The NMOS transistor is also a high breakdown voltage transistor and formed to receive an input/output signal from the metal wiring 17. The impurity concentration of the N-type impurity of the NMOS source/drain electric-field relaxation regions 13A is 5.0×10¹⁶ to 1.0×10¹⁷/cm³.

The region where the NMOS transistor is formed is also isolated by the shallow trench 7. Like the PMOS transistor, a contact region 13C is isolated from the NMOS source/drain electric-field relaxation regions 13A by the shallow trench 7.

The PMOS transistor and the NMOS transistor operate independently. Since the PMOS transistor region 50 and the NMOS transistor region 51 are electrically isolated by the deep trench 8, the PMOS transistor and the NMOS transistor can stably operate without interfering with each other.

The semiconductor device according to the present embodiment has the structure described above. Since the semiconductor device according to the present embodiment includes the P-type well region 4 formed by implanting the impurity into a region of the N-type epitaxial layer, the impurity concentration of the base region can be increased in the transverse bipolar transistor 20 composed of an emitter region including the NMOS source/drain electric-field relaxation regions 13A and the NMOS high-concentration source/drain regions 13B, the base region including the P-type well region 4 and the P-type semiconductor substrate 1, and a collector region including the N-type epitaxial layer 2 and the N-type buried layer 6. Therefore, the current amplification factor h_{FE} of the transverse bipolar transistor 20 can be reduced.

Since the semiconductor device according to the present embodiment includes the N-type epitaxial layer 2 and the N-type buried layer 6 formed by implanting the impurity into the N-type epitaxial layer 2, the impurity concentration of the base region can also be increased in the vertical bipolar transistor 30 composed of an emitter region including the PMOS source/drain electric-field relaxation regions 12A and the PMOS high-concentration source/drain regions 12B, the base region including the N-type epitaxial layer 2 and the N-type buried layer 6, and a collector region including the P-type semiconductor substrate 1 (and the P-type well region 4). Therefore, the current amplification factor h_{FE} of the vertical bipolar transistor 30 can also be reduced.

### (Protecting Action of Transistor)

The P-type semiconductor substrate 1 and the N-type epitaxial layer 2 in the semiconductor device according to the present embodiment form a protection diode. The protection diode protects an internal circuit from surge.

As illustrated in FIG. 2, an internal circuit 155 composed of the PMOS transistor and the NMOS transistor, and a diode 156 are connected in parallel between a VDD terminal 400 and a GND terminal 401. The diode 156 is made of the P-type semiconductor substrate 1 and the N-type epitaxial layer 2.

When a surge (e.g., noise inputted from a power source) is applied from the VDD terminal of this circuit, the surge current flows toward the GND terminal 401 via the diode 156.

The surge is an abnormal voltage of 1 to 2 KV, for example. The operation voltage of the PMOS and NMOS transistors is 20 V. When a voltage breakdown of the PMOS transistor and the NMOS transistor is set to about 25 V, and the voltage breakdown of the parasitic diode made of the N-type epitaxial layer 2 and the P-type semiconductor substrate 1 is set to be not more than the breakdown voltage of the transistor, the transistor can be protected.

### (Production Method)

Next, the production method of the semiconductor device according to the present embodiment will be described. FIGS. 3 to 5 illustrate a production process of the semiconductor device according to the first embodiment. FIGS. 3 to 5 are views of the production process when the NMOS transistor and the PMOS transistor are produced as in FIG. 1.

Firstly, the P-type semiconductor substrate 1 is prepared. For example, a P-type silicon substrate having an impurity concentration of 1×10¹⁷/cm³ is prepared. The impurity may be boron (B).

Then, as illustrated in FIG. 3(a), the N-type epitaxial layer 2 having an impurity concentration of 1×10¹⁶/cm³, and a thickness of 3 μm is grown on the P-type semiconductor substrate 1. For example, a CVD method is employed.

Subsequently, as illustrated in FIG. 3(b), the shallow trench 7 is formed on the N-type epitaxial layer 2 by a known process, and the deep trench 8 is formed on the N-type epitaxial layer 2 and the P-type semiconductor substrate 1. The shallow trench 7 is formed to have a depth of 250 to 500 nm, for example, in order to isolate elements on the same well. The deep trench 8 is formed on the portion serving as a boundary between wells, when the well regions are formed, (boundary between the region 50 (hereinafter referred to as PMOS transistor region 50) where the PMOS transistor is to be formed and the region 51 (hereinafter referred to as NMOS transistor region 51) where the NMOS transistor is to be formed). The deep trench 8 is formed to have a depth of 3.5 μm, for example, in order to penetrate the N-type epitaxial layer 2 and reach the P-type semiconductor substrate 1. In the present embodiment, after the shallow trench 7 is formed, the deep trench 8 is subsequently formed, but the order of the formation may be reversed.

The shallow trench 7 and the deep trench 8 are formed by a known trench forming process (e.g., STI). Specifically, a mask of a silicon nitride film or a silicon oxide film is formed, and a trench etching is performed by using this mask. Then, an inner wall of the trench is oxidized (formation of a silicon oxide film), and then, silicon oxide is deposited by a CVD method to fill the trench. Then, the surface of the P-type semiconductor substrate 1 on which the silicon oxide is deposited is planarized by a CMP process. Thus, the shallow trench 7 and the deep trench 8 can be formed.

Next, as illustrated in FIG. 3(c), the P-type well region 4 is formed on the NMOS transistor region 51. A photoresist is applied onto the P-type semiconductor substrate 1, and a pattern on which the NMOS transistor region 51 is opened is formed on the photoresist by a known photolithography process. Thereafter, P-type impurities are implanted into the N-type epitaxial layer 2 by an ion implantation process with the photoresist having the opening being used as a mask. For example, boron (B) is implanted into the N-type epitaxial layer 2 in order that the impurity concentration of the P-type impurity becomes 4×10¹⁶/cm³. Then, an annealing process is performed to form the P-type well region 4 onto the NMOS transistor region 51.

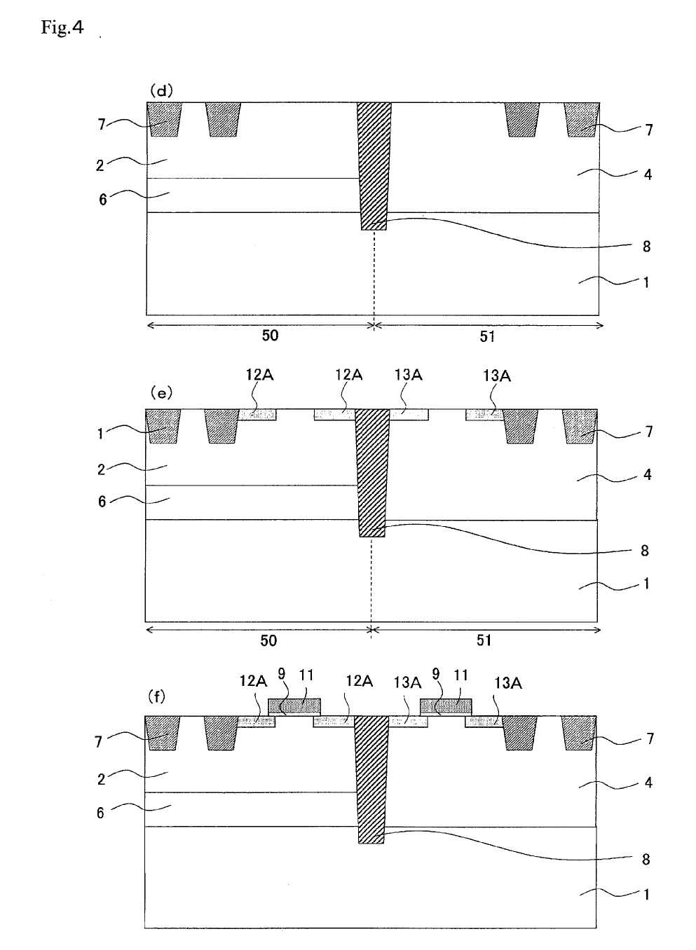

Next, as illustrated in FIG. 4(d), the N-type buried layer 6 is formed in the vicinity of the boundary between the P-type semiconductor substrate 1 and the N-type epitaxial layer 2 in the PMOS transistor region 50. Firstly, a photoresist mask that opens the region on the PMOS transistor region 50 is formed by using a known photolithography process as in FIG. 3(c). Then, N-type impurities are implanted from the photoresist mask with the use of the ion implantation process. For example, phosphor is implanted in the vicinity of the boundary between the P-type semiconductor substrate 1 and the N-type epitaxial layer 2 in order that the concentration of the phosphor (P) becomes 1×10¹⁹/cm³. Then, an annealing process is performed to form the N-type buried layer 6 onto the PMOS transistor region 50.

Next, as illustrated in FIG. 4(e), the PMOS source/drain electric-field relaxation regions 12A and the NMOS source/drain electric-field relaxation regions 13A are formed respectively onto the PMOS transistor region 50 and the NMOS transistor region 51. A photoresist mask that opens the regions on the PMOS source/drain electric-field relaxation regions 12A is formed by a known photolithography process. For example, boron (B) is implanted by using this photoresist as a mask. Similarly, a photoresist mask that opens the regions on the NMOS source/drain electric-field relaxation regions 13A is formed by a known photolithography process. For example, phosphor (P) is implanted by using this photoresist as a mask. Thus, the PMOS source/drain electric-field relaxation regions 12A are formed in the vicinity of the surface of the N-type epitaxial layer 2 in the PMOS transistor region 50, while the NMOS source/drain electric-field relaxation regions 13A are formed in the vicinity of the surface of the P-type well region 4 in the NMOS transistor region 51.

Next, as illustrated in FIG. 4(f), the gate oxide film 9 and the gate electrode 11 having a predetermined pattern are formed in the PMOS transistor region 50 and the NMOS transistor region 51. Firstly, the gate oxide film 9 having a thickness of 30 to 40 nm is grown on the whole surfaces of the N-type epitaxial layer 2 and the P-type well region 4, and a polysilicon having a thickness of 150 to 250 nm is also formed thereon. Then, the gate oxide film 9 and the gate electrode 11 are etched by a known photolithography process, whereby the gate oxide film 9 and the gate electrode 11 having the predetermined pattern are formed. The predetermined pattern of the gate oxide film 9 and the gate electrode 11 is the pattern in which the gate oxide film 9 and the gate electrode 11 are arranged on the region sandwiched between the source electric-field relaxation region and the drain electric-field relaxation region.

In the present embodiment, the PMOS source/drain electric-field relaxation regions 12A and the NMOS source/drain electric-field relaxation regions 13A are formed first, and thereafter, the gate oxide film 9 and the gate electrode 11 are formed. However, like a known MOS transistor, the gate oxide film 9 and the gate electrode 11 may be formed first, and thereafter, the PMOS source/drain electric-field relaxation regions 12A and the NMOS source/drain electric-field relaxation regions 13A may be formed.

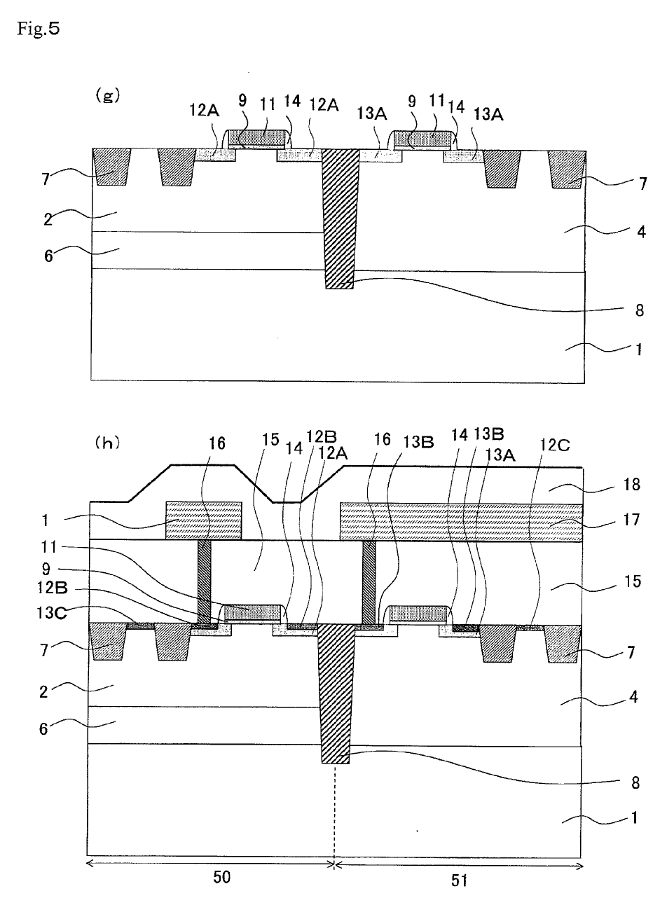

Next, as illustrated in FIG. 5(g), a sidewall 14 is formed at the side faces of the gate oxide film 9 and the gate electrode 11 formed in the process described above. An oxide film (e.g., a silicon oxide film) or a nitride film (e.g., a silicon nitride film) is deposited onto the whole surfaces of the N-type epitaxial layer 2 and the P-type well region 4 by the CVD process, and the deposited film is etched back, whereby the sidewall 14 is formed on the side faces of the gate oxide film 9 and the gate electrode 11. Next, as illustrated in FIG. 5(h), an ion implantation is executed by using the gate electrode 11 and the sidewall 14 as a mask so as to form the high-concentration source/drain regions 12B and 13B (including the contact regions 12C and 13C) as in the known MOS transistor. Further, an interlayer dielectric film 15, the contact hole 16, the metal wiring 17, and a cover glass 18 are formed. Thus, the semiconductor device according to the present embodiment is completed.

### Second Embodiment

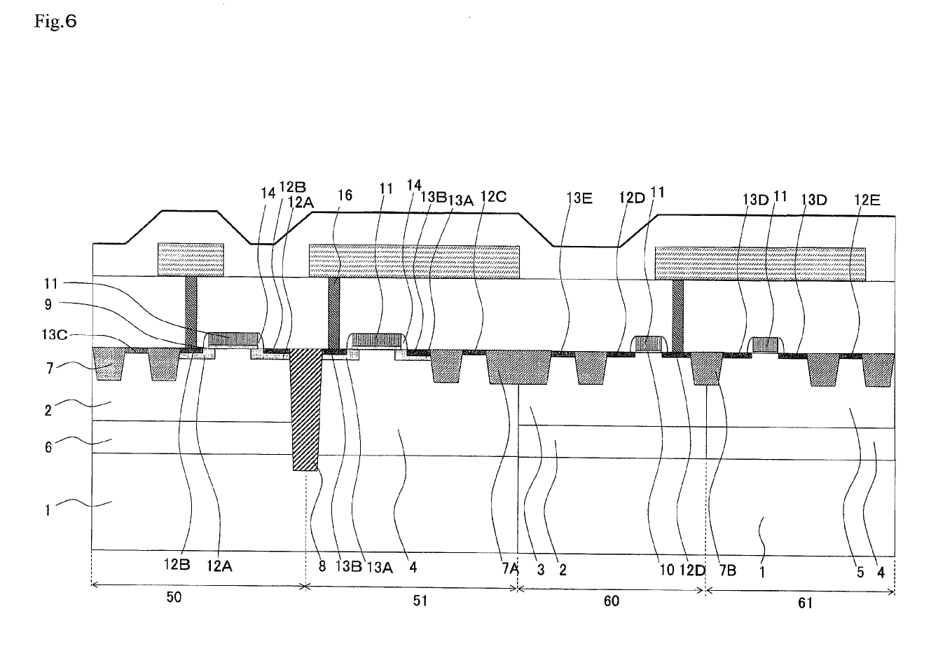

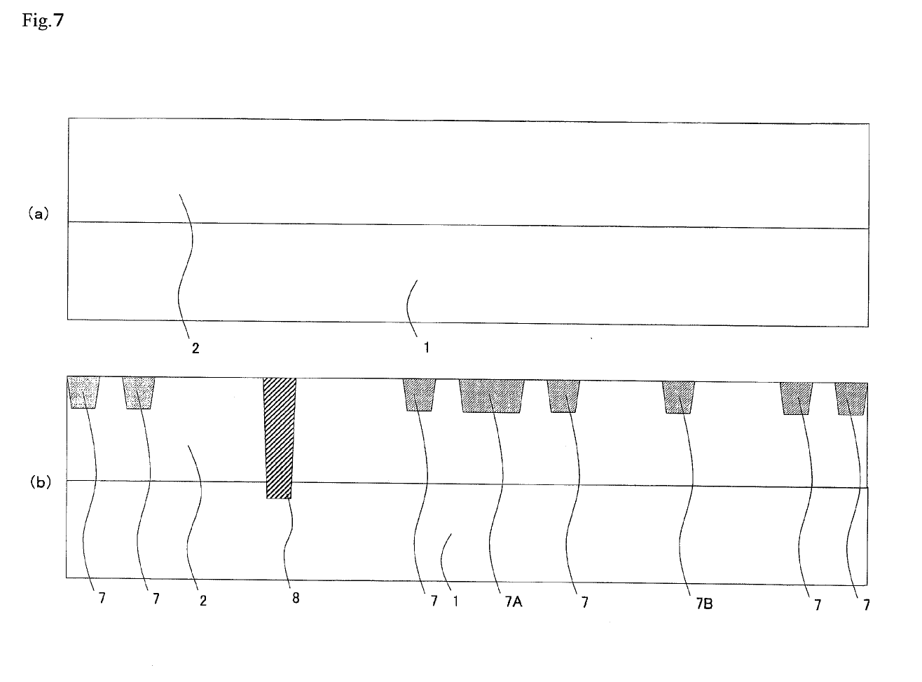

A semiconductor device according to a second embodiment of the present invention will be described with reference to FIGS. 6 to 12. FIG. 6 is a sectional view for describing the semiconductor device according to the second embodiment. FIGS. 7 to 12 are views illustrating a production process of the semiconductor device according to the second embodiment.

As illustrated in FIG. 6, the semiconductor device according to the second embodiment is similar to the semiconductor device in the first embodiment in that it includes the P-type semiconductor substrate 1, the P-type well region 4, the N-type epitaxial layer 2, the N-type buried layer 6, and the deep trench 8, and further includes the PMOS transistor formed on the N-type epitaxial layer 2 and the NMOS transistor formed on the P-type well region 4. The semiconductor device according to the second embodiment further includes an N-type well region 3 and a second P-type well region 5 via a shallow trench 7A, wherein a PMOS low breakdown voltage transistor and an NMOS low breakdown voltage transistor are respectively formed on the well regions 3 and 5.

The structure different from the first embodiment will be described below.

The N-type well region 3 is formed on the N-type epitaxial layer 2 via the shallow trench 7A so as to be adjacent to the PMOS transistor region 50 and the NMOS transistor region 51. The PMOS low breakdown voltage transistor is formed on the N-type well region 3.

The PMOS low breakdown voltage transistor includes PMOS source/drain regions 12D arranged to sandwich a channel region of the N-type well region 3, and the gate electrode 11 arranged on the channel region via a gate oxide film 10.

The gate oxide film 10 is set to have a thickness suitable for the low breakdown voltage transistor, while the N-type well region 3 is set to have a known impurity concentration used for the low breakdown voltage transistor.

The second P-type well region 5 is formed on the N-type epitaxial layer 2 in the same manner as in the N-type well region 3, and arranged in a region adjacent to the N-type well region 3. The NMOS low breakdown voltage transistor is formed on the second P-type well region 5.

The NMOS low breakdown voltage transistor includes NMOS source/drain regions 13D arranged to sandwich a channel region of the second P-type well region 5, and the gate electrode 11 arranged on the channel region via the gate oxide film 10. In the NMOS low breakdown voltage transistor, the gate oxide film 10 is set to have a thickness suitable for the low breakdown voltage transistor, while the P-type well region 5 is set to have a known impurity concentration used for the low breakdown voltage transistor, as in the PMOS low breakdown voltage transistor.

As illustrated in FIG. 6, the semiconductor device according to the second embodiment further has a shallow trench 7B between the N-type well region 3 and the second P-type well region 5.

The PMOS low breakdown voltage transistor and the NMOS low breakdown voltage transistor are isolated by the shallow trench 7B.

The shallow trench 7A and the shallow trench 7B have the structure same as that formed by the STI process. Specifically, they are known shallow trenches.

The semiconductor device according to the second embodiment employs the structure described above. Therefore, the semiconductor device according to this embodiment has the high breakdown voltage transistor and the low breakdown voltage transistor mixedly formed on the P-type semiconductor substrate 1. Further, like the first embodiment, the current amplification factor h_{FE} of the transverse and vertical bipolar transistors 20 and 30, which are parasitic transistors, can be reduced.

### (Production Method)

The production method of the semiconductor device according to the second embodiment will next be described. FIGS. 7 to 11 are views illustrating a production process of the semiconductor device according to the second embodiment, specifically, are views illustrating a production process of the semiconductor device having both the high breakdown voltage transistor and the low breakdown voltage transistor.

As in the first embodiment, the P-type semiconductor substrate 1 having an impurity concentration of 1×10¹⁷/cm³ is firstly prepared.

Then, as illustrated in FIG. 7(a), the N-type epitaxial layer 2 having an impurity concentration of 4×10¹⁶/cm³, and a thickness of 3 μm is grown on the P-type semiconductor substrate 1. This process is the same as the process in FIG. 3(a) described in the first embodiment.

Then, the shallow trench 7 is formed on the N-type epitaxial layer 2, and the deep trench 8 is formed on the N-type epitaxial layer 2 and the P-type semiconductor substrate 1 by the known method as illustrated in FIG. 7(b). This process is also the same as the process in the first embodiment. However, in the second embodiment, the shallow trench 7A is formed at the boundary between the high breakdown voltage transistor regions 50 and 51, and the region (hereinafter referred to as a low breakdown voltage transistor region) where the low breakdown voltage transistor is formed. Even in the low breakdown voltage transistor region, the shallow trench 7B is formed at the boundary between a region 60 (hereinafter referred to as a PMOS low breakdown voltage transistor region 60) where the PMOS low breakdown voltage transistor is to be formed and a region (hereinafter referred to as an NMOS low breakdown voltage transistor region 61) where the NMOS low breakdown voltage transistor is to be formed.

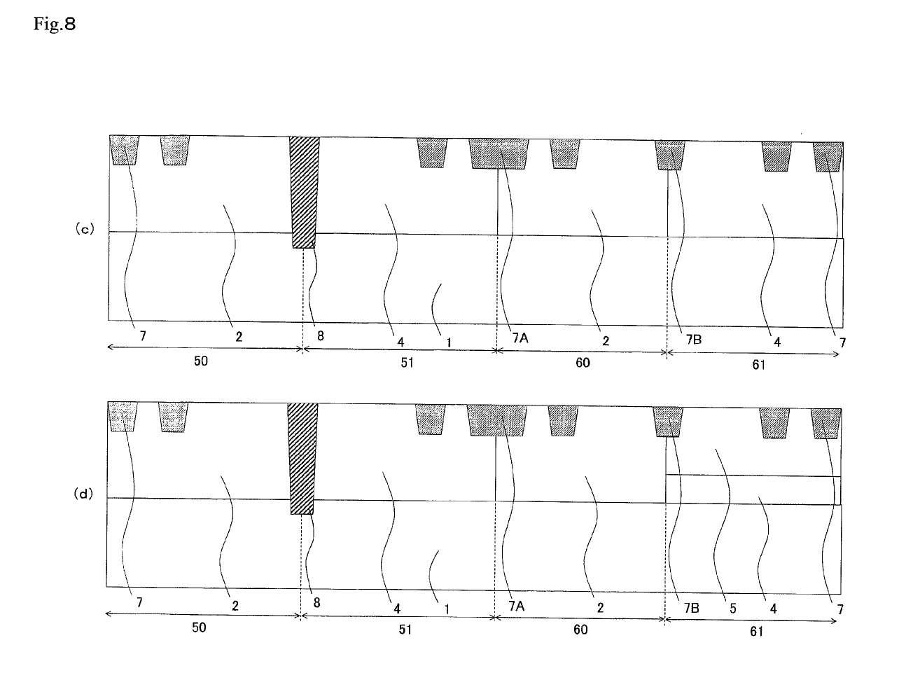

Next, as illustrated in FIG. 8(c), the P-type well region 4 is formed in the NMOS transistor region 51 as in the first embodiment. In the present embodiment, the P-type well region 4 is also formed in the NMOS low breakdown voltage transistor region 61 by implanting a P-type impurity into the N-type epitaxial layer 2. An opening for opening the region on the NMOS low breakdown voltage transistor region 61 is formed on a photoresist mask to be used in this process, whereby the P-type well region 4 is also formed in the NMOS low breakdown voltage transistor region 61.

Next, as illustrated in FIG. 8(d), the second P-type well region 5 is formed in the NMOS low breakdown voltage transistor region 61. A photoresist mask that has an opening corresponding to the region on the NMOS low breakdown voltage transistor region 61 is formed by a known photolithography process. The P-type impurities are implanted into the P-type well region 4 in the NMOS low breakdown voltage transistor 61 by using this photoresist mask. According to this implantation, the well region for the low breakdown voltage transistor is formed. The P-type impurities are implanted by a known ion implantation process or an annealing process.

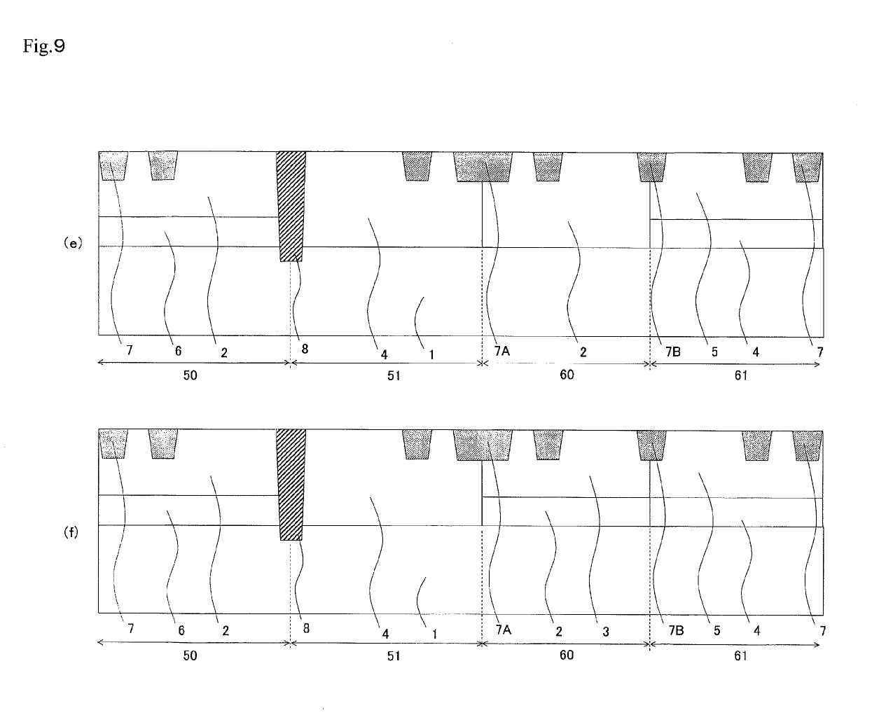

Next, as illustrated in FIG. 9(e), the N-type buried layer 6 is formed in the vicinity of the boundary between the P-type semiconductor substrate 1 and the N-type epitaxial layer 2 in the PMOS transistor region 50. This process is performed in the same manner as in the process in FIG. 4(d) described in the first embodiment. The impurity concentration of the N-type buried layer 6 is 1×10¹⁹/cm³ as in the first embodiment.

Next, as illustrated in FIG. 9(f), the N-type well region 3 is formed in the PMOS low breakdown voltage transistor region 60. A photoresist mask that has an opening corresponding to the region on the PMOS low breakdown voltage transistor region 60 is formed by a known photolithography process. The N-type impurities are implanted by using this photoresist mask. Phosphor is used as the N-type impurity. The N-type impurities are implanted by a known ion implantation process or an annealing process.

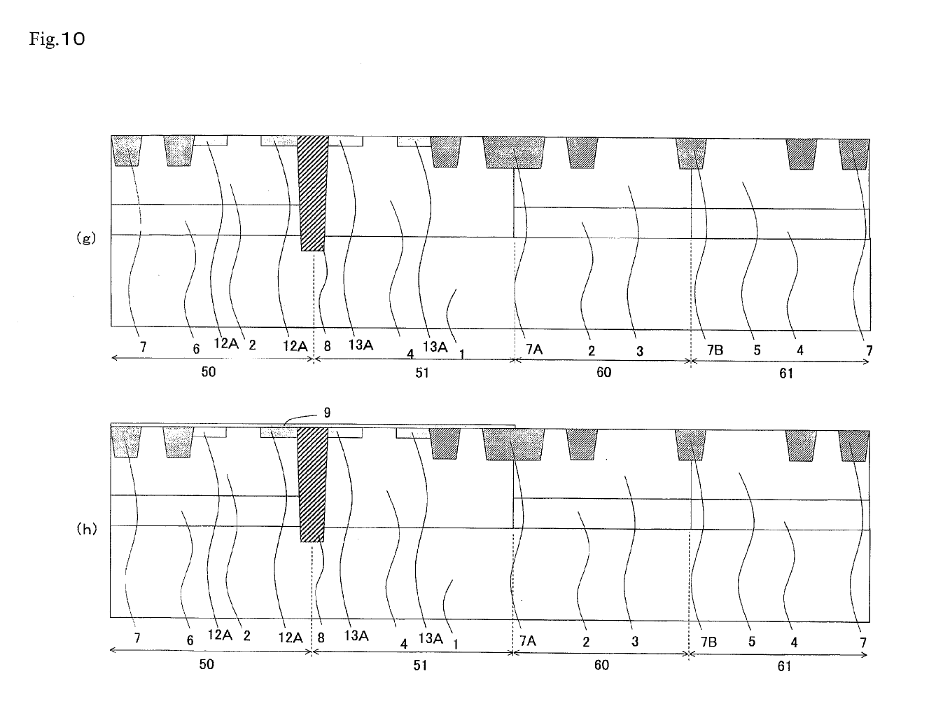

Next, as illustrated in FIG. 10(g), the PMOS source/drain electric-field relaxation regions 12A and the NMOS source/drain electric-field relaxation regions 13A are formed respectively in the PMOS transistor region 50 and the NMOS transistor region 51. This process is performed in the same manner as in the process in FIG. 4(e) described in the first embodiment.

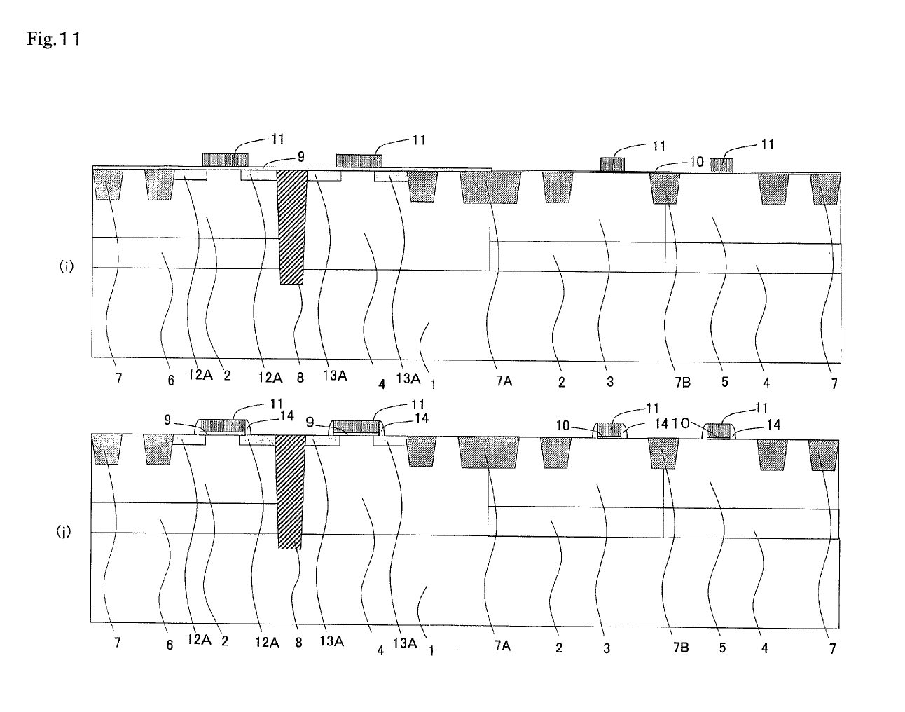

Next, as illustrated in FIG. 10(h), the gate oxide film 9 is formed in the PMOS transistor region 50 and the NMOS transistor region 51. Firstly, the gate oxide film 9 having a thickness of 30 to 40 nm is grown on the whole surface of the P-type semiconductor substrate 1 on which the PMOS source/drain electric-field relaxation regions 12A and the NMOS source/drain electric-field relaxation regions 13A are formed. Then, the gate oxide film 9 is etched by a known photolithography process, whereby the gate oxide film 9 in the PMOS low breakdown voltage transistor region 60 and the NMOS low breakdown voltage transistor region 61 is removed. An HF chemical solution is used for the etching. Thus, the gate oxide film 9 that is arranged so as to cover the PMOS transistor region 50 and the NMOS transistor region 51 is formed. Next, as illustrated in FIG. 11(i), the gate oxide film 10 is formed in the PMOS low breakdown voltage transistor region 60 and the NMOS low breakdown voltage transistor region 61, and further, the gate electrode 11 having a predetermined pattern is formed. Firstly, the gate oxide film 10 having a thickness of 5 to 8 nm is grown on the whole surface of the P-type semiconductor substrate on which the gate oxide film 9 is formed. Then, a polysilicon having a thickness of 150 to 250 nm is deposited onto the whole surface of the P-type semiconductor substrate 1 on which the gate oxide film 10 is formed. Thereafter, etching is performed by a known photolithography process, whereby the gate electrode 11 having the predetermined pattern is formed.

Next, as illustrated in FIG. 11(j), the sidewall 14 is formed on the side face of the gate electrode 11. An oxide film (e.g., a silicon oxide film) or a nitride film (e.g., a silicon nitride film) is deposited onto the whole surface of the P-type semiconductor substrate 1 having the gate electrode 11 formed thereon by the CVD process, and the deposited film is etched back, whereby the sidewall 14 is formed on the side face of the gate electrode 11.

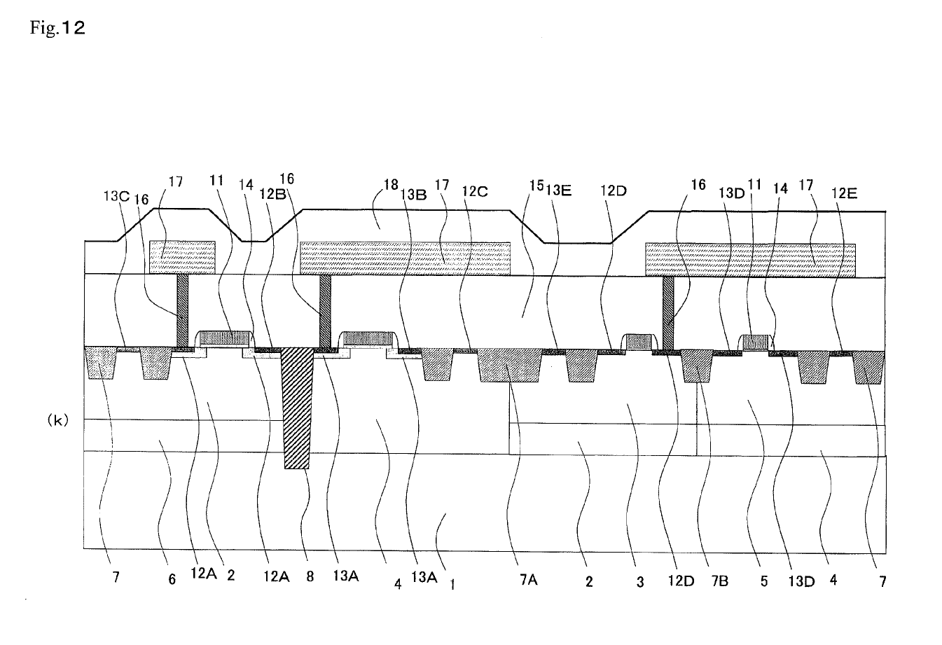

Next, as illustrated in FIG. 12(k), an ion implantation is performed by using the gate electrode 11 and the sidewall 14 as a mask so as to form the high-concentration source/drain regions 12B and 13B, and source/drain regions 12D and 13D (including the contact regions 12C, 13C, 12E and 13E) as in the known MOS transistor. Further, the interlayer dielectric film 15, the contact hole 16, the metal wiring 17, and the cover glass 18 are formed.

Thus, the semiconductor device according to the second embodiment is completed.

The various features in the embodiments described above can be combined to each other. When one embodiment includes plural features, one or plural features are appropriately extracted to be solely adapted or to be adapted in combination to the present invention.

For example, the first and second embodiments are the case in which the P-type semiconductor substrate is used. However, it is apparent that the semiconductor device can easily be formed by using an N-type semiconductor substrate. Therefore, the structure in which the P-type conductive type and the N-type conductive type are replaced with each other is applicable to the present invention.

What is claimed is:

1. A semiconductor device including:
a semiconductor substrate of a first conductive type;
a first well region of the first conductive type formed in the semiconductor substrate;
an epitaxial region of a second conductive type formed in the semiconductor substrate and arranged in a region adjacent to the first well region;
a buried region of the second conductive type that is formed in a region at a lower part of the epitaxial region and that has an impurity concentration higher than that of the epitaxial region;
a trench formed at boundaries between the first well region and the epitaxial region, and between the first well region and the buried region;
a first semiconductor element that is formed on the first well region and that has source and drain regions of the second conductive type; and
a second semiconductor element that is formed on the epitaxial region and has source and drain regions of the first conductive type,
wherein the semiconductor substrate has an impurity concentration higher than that of the first well region, and the trench is formed so as to be deeper than the first well region and the buried region.

2. The semiconductor device according to claim 1, wherein the semiconductor substrate has three times to ten times as much impurity concentration as the first well region.

3. The semiconductor device according to claim 1, wherein the buried region has 100 times to 1000 times as much impurity concentration as the epitaxial region.

4. The semiconductor device according to claim 1, wherein a shallow trench for isolating the first or the second semiconductor element is formed in the first well region or in the epitaxial region.

5. The semiconductor device according to claim 1, wherein the semiconductor substrate and the epitaxial region form a diode so as to protect the second semiconductor element.

6. A production method of a semiconductor device, the method including:
a step of forming an epitaxial region of a second conductive type on a semiconductor substrate of a first conductive type;
a step of forming a trench in the epitaxial region, the trench being deeper than the epitaxial region;
a step of forming a first well region of the first conductive type in a region being in the epitaxial region and being adjacent to the trench;
a step of forming a buried region of the second conductive type in a region that is at a lower part of the epitaxial region, is adjacent to the trench, and sandwiches the trench with the first well region, the buried region having an impurity concentration higher than that of the epitaxial region;
a step of forming source and drain regions of the second conductive type on the first well region; and
a step of forming source and drain regions of the first conductive type on the epitaxial region,
wherein the semiconductor substrate has an impurity concentration higher than that of the first well region formed in the step of forming the first well region.

7. The production method of a semiconductor device according to claim 6, wherein the semiconductor substrate has three times to ten times as much impurity concentration as the first well region formed in the step of forming the first well region.

8. The production method of a semiconductor device according to claim 6, wherein the buried region formed in the step of forming the buried region has 100 times to 1000 times as much impurity concentration as the epitaxial region formed in the step of forming the epitaxial region.

9. The production method of a semiconductor device according to claim 6 further including:
a step of forming, in the first well region or in the epitaxial region, a shallow trench for isolating the source and drain regions from the other regions.
